(19) United States
(12) Patent Application Publication
(10) Pub. No.: US 2007/0023803 A1
(43) Pub. Date: Feb. 1, 2007

(54) CMOS image sensor and method of fabricating the same

(75) Inventor: Kim Jong Min, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/493,270

(22) Filed: Jul. 25, 2006

(30) Foreign Application Priority Data
Jul. 26, 2005 (KR) 10-2005-0067774

(51) Int. Cl. H01L 31/113

(52) U.S. Cl. 257/292

(57) ABSTRACT

A CMOS image sensor and a method of fabricating the same are provided. The CMOS image sensor includes a photodiode region and a transistor region that have a first concentration and are formed on an active region of a first conductive type semiconductor substrate. Additionally, the CMOS image sensor includes a second conductive-type doping region that has a first depth and a second concentration, formed in the photodiode region and having a plurality of parallel, spaced apart portions (or bars) therein; and a high concentration first conductive-type doping region formed in the photodiode region having a second depth shallower than the first depth and a third concentration higher than the second concentration.

### BACKGROUND OF THE INVENTION

1. Field of the Invention

The present invention relates to a CMOS image sensor and a method of fabricating the same.

2. Description of the Related Art

Examples of an image sensor are a charged coupled device (CCD) and a complementary metal oxide semiconductor (CMOS) image sensor.

The CMOS image sensor includes a photodiode of a light receiving unit, and a CMOS unit obtaining an electrical signal by using charges accumulated on the photodiode. The CMOS image sensor in this structure has been developed to increase a depletion region for improving efficiency of light that is incident into a photodiode. When the efficiency of light increases, regions that the photodiode occupies are reduced such that the degree of integration in the devices can be improved.

A related art CMOS image sensor and a method of fabricating the same are described with referent to FIGS. 1 and 2.

Referring to FIG. 1, a field oxide layer 102 defining a field region and an active region is formed in a P-type semiconductor substrate 100. A transistor 104 is formed on or in the active region of the semiconductor substrate 100. An N-type doping region 106a of a photodiode source is formed with a predetermined depth on an entire surface of the semiconductor substrate 100 in the active region. A P-type doping region 106b is formed with a shallower depth than the N-type doping region 106a on the entire surface of the semiconductor substrate 100 in the active region. A photodiode 106 is formed by the doping regions 106a and 106b. Referring to FIG. 1, a reference number 108 represents a drain region.

The photodiode 106 is formed according to a method below.

First, a field oxide layer 102 is formed on a predetermined region of the P-type semiconductor substrate 100 using a local oxidation of silicon (LOCOS) or a shallow trench isolation (STI) process. The field region and the active region are defined on the semiconductor substrate 100 by the field oxide layer 102.

After the forming of the oxide layer 102, the N-type doping region 106a is formed with a predetermined depth by implanting an N-type impurity ion on an entire surface of the P-type semiconductor substrate 100 in the active region. The N-type impurity has a lower concentration than an impurity of the semiconductor substrate 100. The N-type doping region 106a may be formed using a mask pattern P1, illustrated as a dotted line in FIG. 2.

Referring back to FIG. 1, a high concentration P-type doping region 106b is formed by implanting a high concentration P-type impurity ion in an entire surface of the semiconductor substrate 100 in the active region with the N-type doping region 106a already implanted therein. Referring to FIG. 2, a reference number P3 represents the active region mask pattern defining the field region and the active region. A reference number P2 represents a gate pattern of a transistor (e.g., transistor 104 in FIG. 1).

Since the photodiode in the related art CMOS image sensor is believed to have only a depletion region in a vertical direction as a photoelectric conversion region, a photoelectric efficiency at each unit region may be low. Also, there may be a limitation in reducing the size and/or proportion of the region that the photodiode occupies in a unit pixel. Thus, there are challenges in integrating the related art CMOS image sensor as device dimensions decrease.

Moreover, to increase sensitivity of the photodiode, the high concentration P-type doping region and N-type doping region need to be completely depleted. However, in the photodiode, the depletion region can be reduced in a vertical direction by electrons and holes that may accumulate (e.g., at the interface between a doping region and the depletion region), according to a photoelectron tunneling phenomenon. Therefore, the photodiode efficiency may be reduced.

Additionally, since a related art CMOS image sensor may form an N-type doping region having a lower concentration than the semiconductor substrate, there can be a limitation in increasing a doping concentration of the high concentration P-type doping region. Therefore, the tunneling efficiency of photon may be reduced. That is, when the related art CMOS image sensor forms an N-type doping region having a lower concentration than the semiconductor substrate, the capability of the N-type doping region to maintain electrons decreases. Consequently, a dynamic range of the photodiode and/or unit pixel (e.g., a voltage swing of an output in a unit pixel) decreases.

### SUMMARY OF THE INVENTION

Accordingly, the present invention is directed to a CMOS image sensor and a method of fabricating the same that substantially obviates one or more problems due to limitations and disadvantages of the related art.

An object of the present invention is to provide a CMOS image sensor with improved photodiode sensitivity and device integration, and a method of fabricating the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, there is provided a CMOS image sensor including a photodiode region and a transistor region in an active region of a semiconductor substrate of a first conductive type having a first concentration, the CMOS image sensor including: a second conductive-type doping region in the photodiode region that has a first depth, a second concentration, and a plurality of parallel, spaced-apart portions (or bars), preferably towards one side of the second conductive-type doping region; and a high concentration first conductive-type doping region in the photodiode region having a second depth shallower than the first depth and a third concentration higher than the second concentration.

In another aspect of the present invention, there is provided a method of fabricating a CMOS image sensor including a photodiode region and a transistor region in an active region of a semiconductor substrate of a first conductive type having a first concentration, the method including: forming a second conductive-type doping region in the photodiode region having a first depth, a second concentration, and a plurality of parallel, spaced-apart portions (or bars), preferably towards one side of the second conductive-type doping region; and forming a high concentration first conductive-type doping region in the photodiode region with a second depth shallower than the first depth and a third concentration higher than the second concentration.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a related art CMOS image sensor;

FIG. 2 is a view of a mask pattern for forming a photodiode of FIG. 1;

FIG. 3 is a sectional view of a CMOS image sensor according to an embodiment of the present invention;

FIG. 4 is a sectional view of the photodiode region of the CMOS image sensor of FIG. 3 taken perpendicularly in and out of the plane of the page, along line IV-IV; and

FIG. 5 is a mask pattern for forming the photodiode of FIGS. 3 and 4.

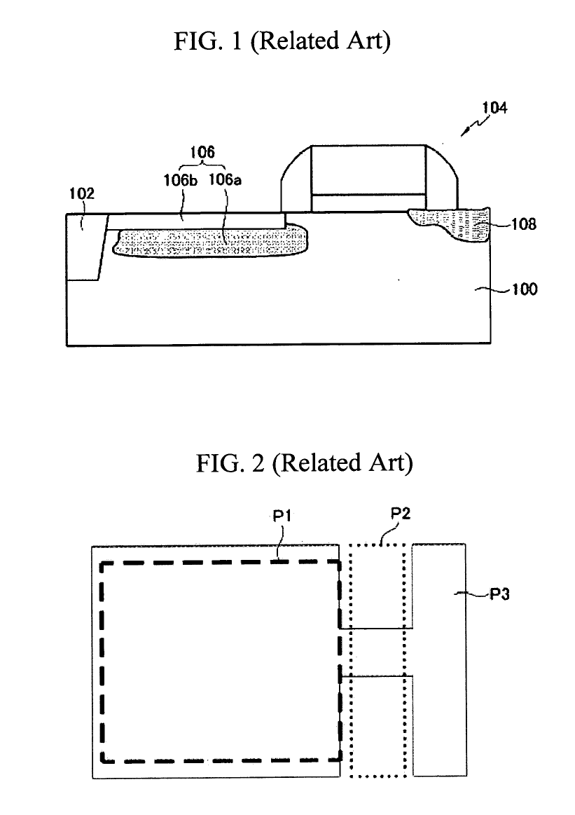

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

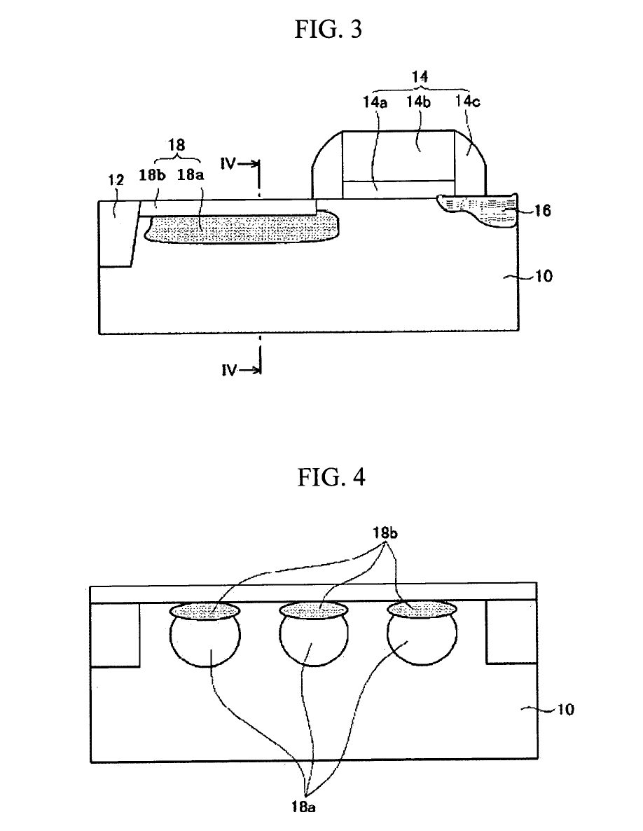

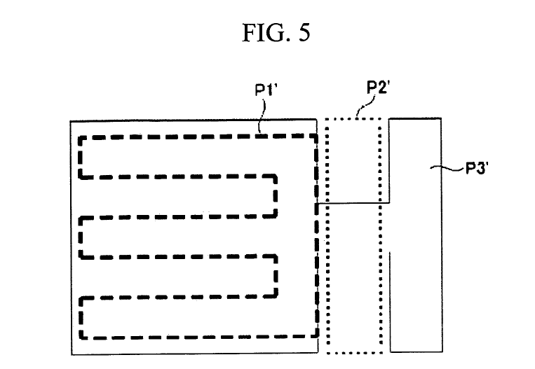

FIG. 3 is a sectional view of a CMOS image sensor according to an embodiment of the present invention. FIG. 4 is a sectional view taken along line IV-IV. FIG. 5 is a mask pattern for forming a photodiode of FIGS. 3 and 4.

As illustrated above, the CMOS image sensor includes P-type semiconductor substrate 10. The P-type semiconductor substrate 10 comprises or consists essentially of a wafer selected from the group consisting of a Si wafer, a Sn wafer, a Ge wafer, a SiGe wafer, a GaAs wafer, an InSb wafer, and an AlAs wafer. A field oxide layer 12 defining a field region and an active region is formed on a predetermined region of the P-type semiconductor substrate 10. The field oxide layer 12 can be formed using a STI process and/or a LOCOS process.

A transistor 14 including a gate insulation layer 14a, a gate 14b, and a spacer layer 14c is formed on an active region formed by the field oxide layer 12. A drain region 16 is formed on a P-type semiconductor substrate 10 below the transistor 14. An N-type doping region 18a of a photodiode source is formed having a first depth on a portion of the semiconductor substrate 10 of the active region. As illustrated in FIGS. 4 and 5, one side of the N-type doping region 18a can comprise a plurality of parallel bar shapes, each formed a predetermined distance apart from an adjacent one. Moreover, the N-type doping region 18a can be formed in a finger-type pattern (e.g., having a first portion adjacent to and parallel with a first border or edge of the photodiode region, and a plurality of portions spaced apart from each other, but in contact at one end with the perpendicular to the first portion, and which may be substantially parallel with second and third opposed borders or edges of the photodiode region). For example, the N-type doping region 18a can be formed in the finger-type pattern having three bars. The number of bars is not limited to three.

The N-type doping region 18a can be formed by implanting an N-type impurity using a plasma ion implantation process. For example, the N-type doping region 18a can be formed by implanting phosphorus ions, arsenic ions, or phosphorus ions and arsenic ions (the latter combination can be implanted simultaneously). When implanting the N-type impurity, a mask pattern P1′ of FIG. 5 can be used to form the N-type doping region 18a in the finger-type pattern.

Referring to FIG. 5, a reference number P2′ represents a gate pattern. A reference number P3′ represents an active region pattern.

The N-type doping region 18a in the finger-type pattern, which is formed by using the mask pattern P1′ of FIG. 5, includes a sufficient depletion region in a side (horizontal) direction between fingers of the finger-type pattern. Therefore, the sensitivity of a photodiode 18 more improves than the sensitivity in the related art.

Additionally, the CMOS image sensor includes the N-type doping region 18a having higher concentration than the semiconductor substrate 10. Consequently, the capability of the N-type doping region 18a to maintain electrons can be improved, and there is provided a unit pixel of a CMOS image sensor that has a relatively large dynamic range that can be reflected in the voltage swing of an output end in the unit pixel. When the dynamic range increases, the resolution of the image sensor is improved.

Moreover, a high concentration P-type doping region 18b having a second depth shallower than the first depth of the N-type doping region 18a can be formed on entire surface of the semiconductor substrate 10 in the active region. The high concentration P-type doping region 18b can be formed by implanting a high concentration P-type impurity ion using a plasma ion implantation process. Alternatively, the high concentration P-type doping region 18b can be formed in a pattern identical to that of the N-type doping region 18a by using the mask pattern P1′ that is used when forming the N-type doping region 18a. Therefore, when the top of the N-type doping region 18a contacts the top of the substrate 10, a failure to form the depletion region can be prevented.

Additionally, as described above, the high concentration P-type doping region 18b can be formed on an entire surface of the photodiode 18.

An amount (e.g., a dose or concentration) of the high concentration P-type impurity ion that is implanted in the high concentration P-type doping region 18b is generally larger than an amount of the N-type impurity ion that is implanted in the N-type doping region 18a.

In the CMOS image sensor having the photodiode 18, sides (i.e., portions between fingers in the N-type doping region 18a) are depleted such that a depletion region has a larger volume than a corresponding depletion region in the related art. Additionally, when the depletion region is reduced by electrons and holes that may accumulate according to a photoelectron tunneling phenomenon, a decreasing rate (e.g., the rate of decrease in the depletion region volume) can be slowed down. Accordingly, the reduction of a photoelectric conversion efficiency at each unit region can be reduced or prevented.

The CMOS image sensor includes the finger-type mask pattern of the photodiode 18 used in a unit pixel. Moreover, the CMOS image sensor includes the depletion region of the photodiode contact in a vertical direction and the depletion region(s) between fingers. The depletion region therefore has a larger volume at each unit region than a corresponding photodiode region in the related art. The photoelectric conversion efficiency at each unit region can be improved to form a highly integrated device. Since the volume of the depletion region may increase, sensitivity can be improved. Moreover, the drastic efficiency reduction that may be caused by photoelectron tunneling can be prevented.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A CMOS (complementary metal oxide semiconductor) image sensor including a photodiode region and a transistor region in an active region of a semiconductor substrate of a first conductive type having a first concentration, the CMOS image sensor comprising:
a second conductive-type doping region in the photodiode region, having a first depth, a second concentration, and a plurality of parallel, spaced-apart portions; and
a high concentration first conductive-type doping region in the photodiode region at a second depth shallower than the first depth and having a third concentration higher than the second concentration.

2. The CMOS image sensor according to claim 1, wherein the second conductive-type doping region comprises a finger-type pattern.

3. The CMOS image sensor according to claim 1, wherein the second conductive-type doping region comprises a finger-type pattern having three parallel, spaced-apart portions.

4. The CMOS image sensor according to claim 1, further comprising a depletion layer in a vertical direction between the plurality of parallel, spaced-apart portions.

5. The CMOS image sensor according to claim 1, wherein the second concentration is higher than the first concentration.

6. The CMOS image sensor according to claim 1, wherein the high concentration first conductive-type doping region has a pattern substantially identical to that of the second conductive-type doping region.

7. The CMOS image sensor according to claim 1, wherein the high concentration first conductive-type doping region covers substantially an entire surface of the photodiode region.

8. The CMOS image sensor according to claim 1, wherein the semiconductor substrate comprises a wafer selected from the group consisting of a Si wafer, a Sn wafer, a Ge wafer, a SiGe wafer, a GaAs wafer, an InSb wafer, and an AlAs wafer.

9. The CMOS image sensor according to claim 1, wherein the second conductive-type impurity ion comprises a phosphorous ion and/or an arsenic ion.

10. A method of fabricating a CMOS image sensor including a photodiode region and a transistor region in an active region of a semiconductor substrate of a first conductive type having a first concentration, the method comprising:
forming a second conductive-type doping region in the photodiode region having a first depth, a second concentration, and a plurality of parallel, spaced apart portions; and
forming a high concentration first conductive-type doping region in the photodiode region having a second depth shallower than the first depth and a third concentration higher than the second concentration.

11. The method according to claim 10, wherein the second conductive-type doping region comprises a finger-type pattern.

12. The method according to claim 10, wherein the second conductive-type doping region comprises a finger-type pattern having three parallel, spaced apart portions.

13. The method according to claim 10, further comprising forming a mask for the second conductive-type doping region a finger-type pattern.

14. The method according to claim 10, further comprising forming a mask for the second conductive-type doping region in a finger-type pattern having three parallel, spaced apart portions.

15. The method according to claim 10, further comprising forming a depletion layer in a vertical direction between the plurality of parallel, spaced apart portions.

16. The method according to claim 10, wherein the second concentration is higher than the first concentration.

17. The method according to claim 10, wherein the high concentration first conductive-type doping region has a pattern substantially identical to that of the second conductive-type doping region.

18. The method according to claim 10, comprising forming the high concentration first conductive-type doping region on substantially an entire surface of the photodiode region.

19. The method according to claim 10, wherein the semiconductor substrate comprises a wafer selected from the group consisting of a Si wafer, a Sn wafer, a Ge wafer, a SiGe wafer, a GaAs wafer, an InSb wafer, and an AlAs wafer.

20. The method according to claim 10, wherein the second conductive-type doping region comprises an impurity ion selected from the group consisting of a phosphorous ion and an arsenic ion.
